(19) United States
(12) Patent Application Publication
(10) Pub. No.: US 2024/0047898 A1
(43) Pub. Date: Feb. 8, 2024

(54) Contacts and Connectors

(71) Applicant: Tyco Electronics Japan G.K., Kawasaki-shi (JP)

(72) Inventors: Masaaki Iwasaki, Kawasaki-shi (JP); Junya Tsuji, Kawasaki (JP)

(73) Assignee: Tyco Electronics Japan G.K., Kawasaki-shi (JP)

(21) Appl. No.: 18/365,526

(22) Filed: Aug. 4, 2023

(30) Foreign Application Priority Data
Aug. 4, 2022 (JP) 2022-124460

(51) Int. Cl. H01R 4/02; H01R 12/72

(52) U.S. Cl. CPC H01R 4/02; H01R 12/727

(57) ABSTRACT

A contact for electrically connecting a first object and a second object includes a main body adapted to be connected to the first object, and a joint portion protruding from the main body toward the second object. The joint portion is adapted to be joined to the second object via solder. A part or portion of a contour of the joint portion is formed in an anchor shape. The anchor shape defines a normal vector including a vector component extending in an opposite direction to a protruding direction of the joint portion.

### CROSS-REFERENCE TO RELATED APPLICATIONS

This application claims the benefit of Japanese Patent Application No. 2022-124460 filed on Aug. 4, 2022, the whole disclosure of which is incorporated herein by reference.

### FIELD OF THE INVENTION

The present invention relates to a contact joined to an object via a solder, and a connector including the contact.

### BACKGROUND

In know electronic arrangements, a first circuit structure equivalent to a circuit board, an integrated circuit (IC) package or the like, and a second circuit structure equivalent to another circuit board are connected in a pluggable and unpluggable manner using a connector surface-mounted on the first circuit structure.

A zero insertion force (ZIF) connector may be used to connect pins of a pin grid array (PGA) type IC package to conductive pads on the first circuit structure or circuit board. Such a connector includes a large number of contacts arranged in a matrix following the PGA, a housing accommodating the contacts, and a slider for driving the contacts to press against the pins of the IC package. A solder ball is provided at a tail end of the each of the contacts exposed at the circuit board side of the housing. The solder ball is arranged so as to correspond to the pin of the IC package to form a ball grid array (BGA). The group of contacts are joined to the circuit board via the BGA and solder paste applied to the pads of the circuit board. In order to unplug the connector from a mating counterpart, an external force must be placed on at least one of the connectors. This force produces a load on the solder joint between the contact and the circuit board or the like. The load can cause damage or failure of the solder joint(s), particularly after repeated unplugging events.

### SUMMARY

According to an embodiment of the present disclosure, a contact for electrically connecting a first object and a second object includes a main body adapted to be connected to the first object, and a joint portion protruding from the main body toward the second object. The joint portion is adapted to be joined to the second object via a solder. A part or portion of a contour of the joint portion is formed in an anchor shape. The anchor shape defines a normal vector including a vector component extending in an opposite direction to a protruding direction of the joint portion.

### BRIEF DESCRIPTION OF THE DRAWINGS

The invention will now be described by way of example with reference to the accompanying Figures, of which:

FIG. 1(a) is an isometric view of a first connector and a second connector according to an embodiment of the present invention, and FIG. 1(b) is a schematic view showing the first connector and the second connector in a mated state;

FIG. 2(a) is a cross-sectional view of a second assembly taken along the line IIa-IIa in FIG. 1(a), and FIG. 2(b) is a cross sectional view of a first assembly taken along the line IIb-IIb in FIG. 1(a);

FIG. 3(a) is a top view of the first connector, FIG. 3(b) is a side view as viewed in the direction of an arrow IIIb in FIG. 3(a), and FIG. 3(c) is a side view as viewed in the direction of an arrow Mc in FIG. 3(a);

FIG. 4(a) is an isometric view of a contact, FIG. 4(b) is a top view of the contact, and FIG. 4(c) is a schematic view for illustrating an anchor shape of a joint portion of the contact;

FIG. 5 is an enlarged view of a portion V in FIG. 1(a);

FIG. 6(a) is an enlarged view of some contacts of the first connector, and FIG. 6(b) is a cross sectional view along a line VIb-VIb in FIG. 3(a);

FIG. 7(a) is an isometric view showing a solder ball provided at the joint portion of the contact, and FIG. 7(b) is an isometric view showing the joint portion of the contact exposed from a housing;

FIG. 8(a) is a vertical sectional view of a portion of the contact and the solder ball, and FIG. 8(b) is a diagram showing the contact in a state of being joined to a circuit board via a solder;

FIG. 9 is a diagram showing a contact of a comparative example in a state of being joined to a circuit board via a solder;

FIG. 10(a) is a diagram showing a contact according to a first modification, and FIG. 10(b) is a diagram showing a contact according to a second modification; and

FIG. 11(a) is a diagram showing a contact according to a third modification, FIG. 11(b) is a diagram showing a contact according to a fourth modification, and FIG. 11(c) is a diagram showing a contact according to a fifth modification.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An external force applied to a connector assembly when the connector is unplugged from a mating counterpart causes a load on the solder joint between the contact and the circuit board or the like. An object of the present invention is to improve a retaining force to retain the contact to the circuit board or the like against the external force. A contact according to an embodiment of the present invention includes a joint or joining portion having an anchor shape. This shape increases the contact area to which the solder is joined, thereby increasing joining strength. As a result, an increase in the retaining force and the breaking strength ofjoint is realized for preventing the joint portion from being pulled out of the solder. In other words, the retaining force fixing the contact to the circuit board or the like against an external force is improved.

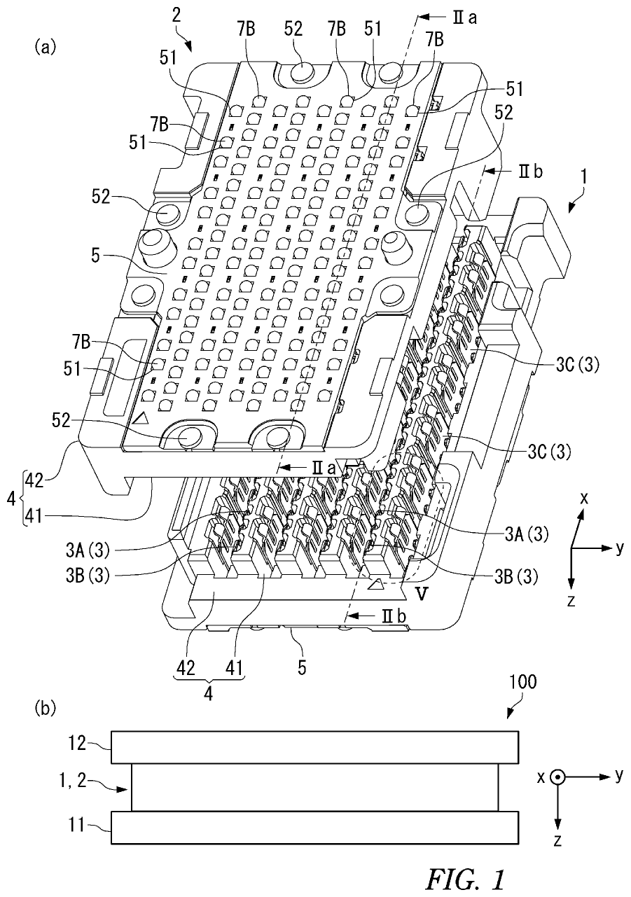

FIG. 1(a) illustrates an exemplary first connector 1 and a second connector 2 defining a connector or connector assembly according to an embodiment of the present disclosure. The first connector 1 includes a plurality of contacts 3 arranged in a two-dimensional array, a main housing 4, and a sub-housing 5. The second connector 2 similarly includes a plurality of contacts 3 arranged in a two-dimensional array, a main housing 4, and a sub-housing 5.

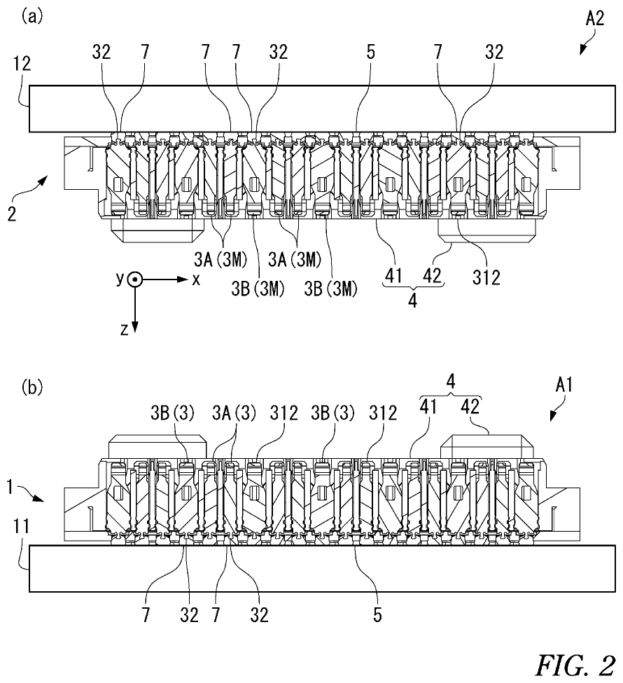

The contact group (i.e., the group of the plurality of contacts 3) of the first connector 1 is joined to a first substrate or circuit board 11 via solder 7, as shown in FIG. 2(b). The contact group of the second connector 2 is joined to a second substrate or circuit board 12 via solder 7, as shown in FIG. 2(a). When the first connector 1 and the second connector 2 are mated as schematically shown in FIG. 1(b), the contact 3 of the first connector 1 and the contact 3 of the second connector 2 are brought into contact with each other and electrically connected.

This results in a connection between the first circuit or circuit board 11 and the second circuit or circuit board 12 arranged in parallel with the first circuit board via the contact 3 of the first connector 1 and the contact 3 of the second connector 2. The first connector 1 and the second connector 2 are pluggable into, and unpluggable from, each other in a direction orthogonal to the first circuit board 11 and the second circuit board 12 (in a z-direction as a plugging/unplugging direction). An x-y-z orthogonal coordinate system is shown in each figure for reference.

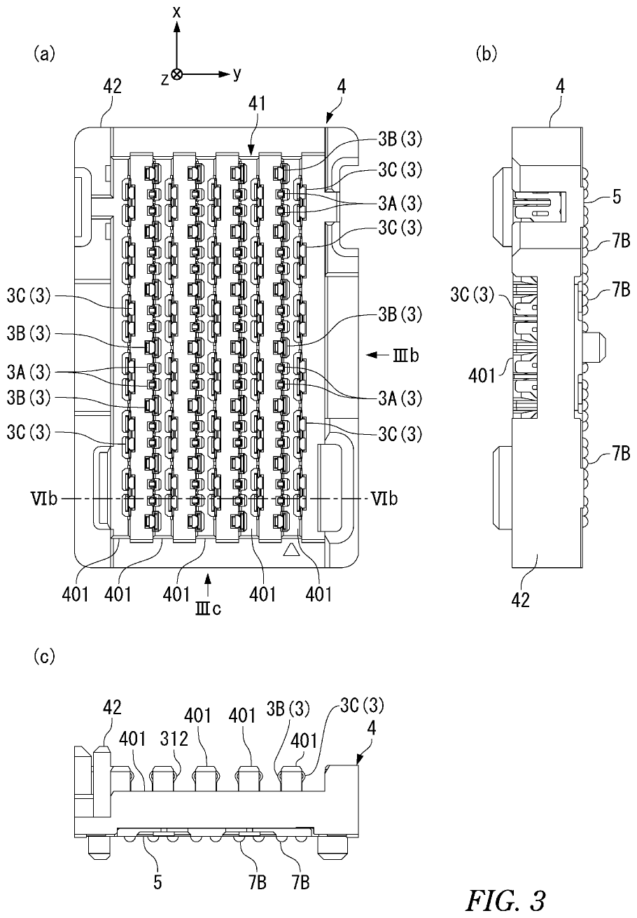

The electrically conductive contact 3 of the present embodiment collectively refers to a plurality of kinds of contacts used for different purposes, and specifically includes a signal contact 3A, a ground contact 3B, and a ground shield 3C, as shown in FIG. 1(a) and FIG. 3(a). The signal contact 3A and the ground contact 3B are used for signal transmission between the first circuit board 11 and the second circuit board 12. The ground shield 3C provides an electromagnetic shield. The signal contact 3A, the ground contact 3B, and the ground shield 3C are all arranged over an x-y plane in their own arrangement patterns and retained in the main housing 4.

In the present embodiment, the respective contacts of the same kind of the first connector 1 and the second connector 2 are connected to each other. For example, the signal contact 3A of the first connector 1 and the signal contact 3A of the second connector 2 are connected to each other. The contacts of the same kind are formed in the same shape. The contacts of the same kind are arranged in the same position when the first connector 1 and the second connector 2 are arranged opposite each other.

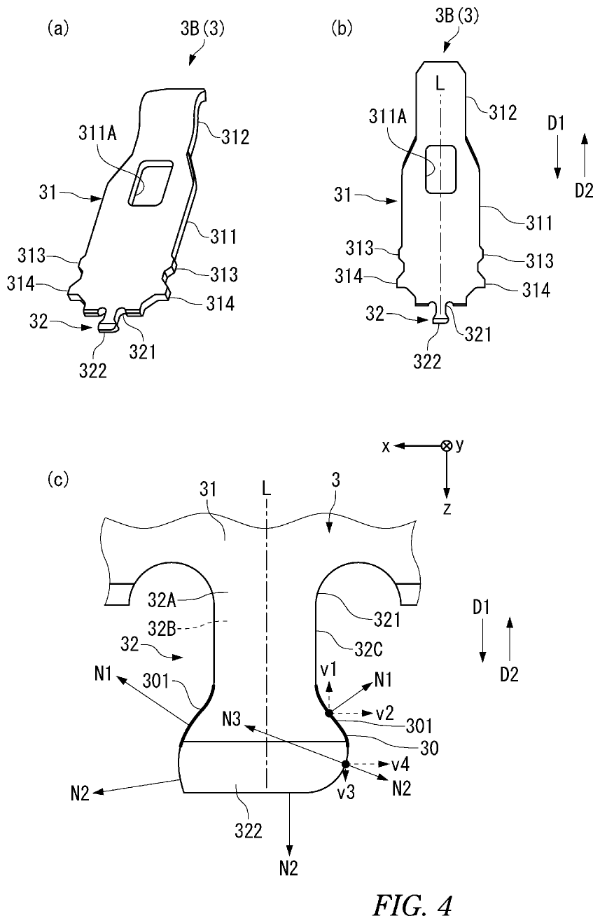

FIGS. 4(a) and 4(b) show the ground contact 3B, which may be representative of each of the three types of contacts 3A,3B,3C, or which may differ from the other types of contacts, as set forth in detail herein. In one embodiment, the width (x-directional dimension) of the signal contact 3A is narrower than that of the ground contact 3B. The ground shield 3C is given a width corresponding to a total width of the three contacts 3: two signal contacts 3A and one ground contact 3B. The contacts 3 of the three types 3A,3B,3C are all given a predetermined shape by stamping and forming a sheet material composed of, for example, a copper alloy.

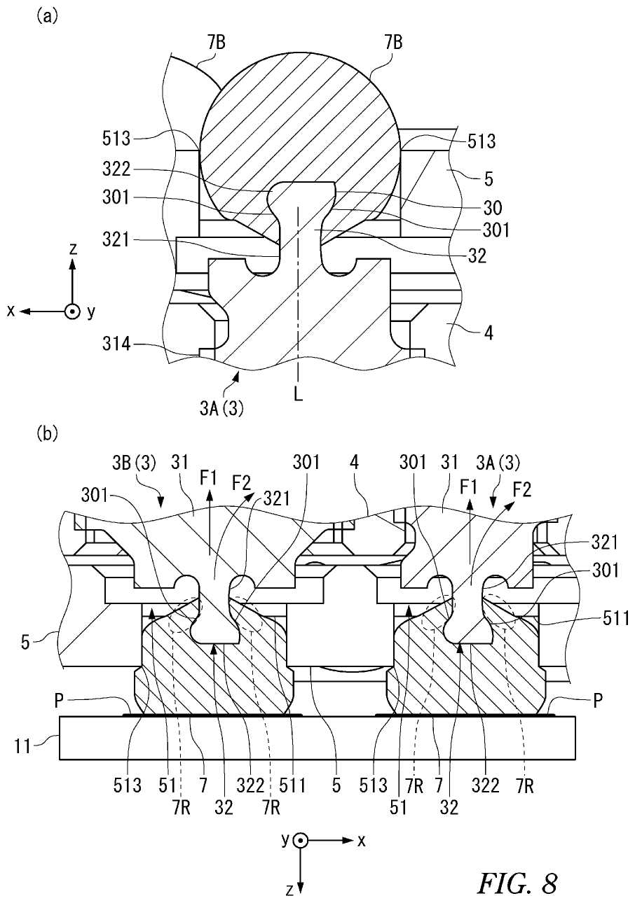

The ground contact 3B is brought into contact with a mating or counter-contact 3M (FIG. 2(a)) as a first object to be connected, and is also joined via a solder 7 to a pad P (e.g., a conductive solder pad, FIG. 8(b)) as a second object to be connected formed on a counter-circuit board, thereby electrically connecting the counter-contact 3M and the pad P. If the contact 3 of the first connector 1 is used as the basis, the counter-contact 3M, as shown in FIGS. 2(a) and 2(b), corresponds to the contact 3 of the second connector 2. If the contact 3 of the second connector 2 is used as the basis, the counter-contact 3M corresponds to the contact 3 of the first connector 1. The ground contact 3B of the present embodiment is formed substantially symmetrically about a center line L set parallel with the plugging/unplugging direction z, though this is not required.

The ground contact 3B includes a contact main body 31 configured or adapted to be connectable to the counter-contact 3M, and a joint portion 32 protruding from the contact main body 31 toward the pad P and configured or adapted to be joinable to the pad P via a solder. The joint portion 32 is referred to as a contact tail. The ground shield 3C includes two joint portions 32. The joint portion 32 can be plated with, for example, nickel, tin, or the like.

The contact main body 31 extends in the plugging/unplugging direction z from the joint portion 32 side to a leading end portion 312 through an intermediate portion 311. The width of the leading end portion 312 is narrower than that of the intermediate portion 311. The leading end portion 312 is bent in a sheet thickness direction and is thereby given elasticity. A hole 311A for adjusting a spring constant of the contact 3 is formed, if necessary, in the intermediate portion 311.

In addition, a press-fit protrusion 313 adapted to be retained in the main housing 4 and a stopper protrusion 314 adapted to set or fix a press-fit depth are formed on the contact main body 31. The press-fit protrusion 313 and the stopper protrusion 314 are formed on opposite sides in the widthwise direction x of the contact main body 31.

The joint portion 32 extends from a proximal end 321 continuous with the contact main body 31 to a distal end 322 close to the pad P on the circuit board 11,12. The width of the proximal end 321 is narrower than that of the leading end portion 312 which is narrow in width than the contact main body 31. The distal end 322 and adjoining portions of the contact 3 are crushed in the sheet thickness direction, thereby becoming thinner gradually toward the distal end 322.

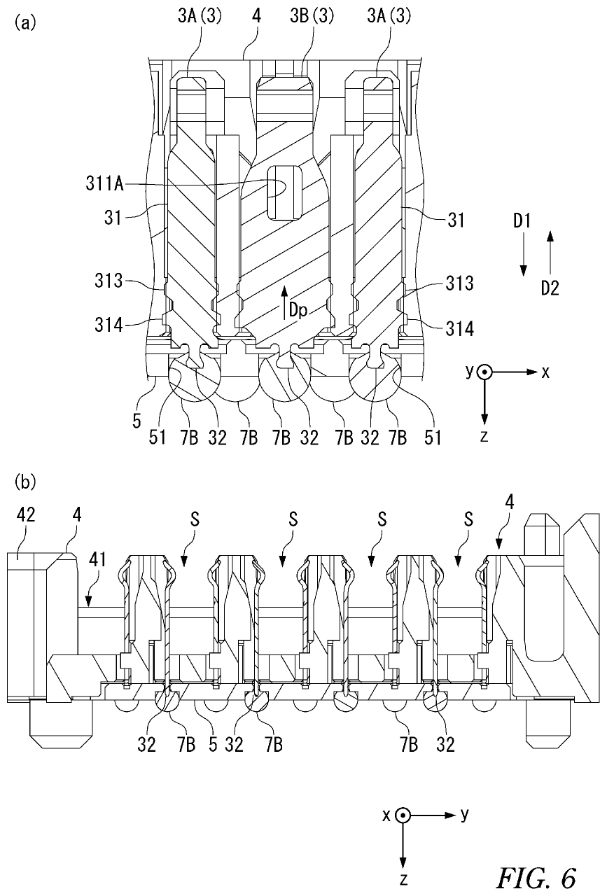

The joint portion 32 is provided with a solder ball 7B (FIG. 6(a)). The solder ball 7B is equivalent to a spherical solder agglomerate. The solder ball 7B is composed of, for example, an alloy of tin, silver, and copper. The joint portion 32 is formed in a smooth shape so that molten solder can easily be filled in around the joint portion 32, and in order to avoid stress concentration on the solder solidified and the joint portion 32.

The signal contact 3A and the ground shield 3C are different in shape from the ground contact 3B but include a similar contact main body 31 and a similar joint portion 32. The joint portions 32 provided to the respective contacts 3 of the present embodiment are all given an anchor shape which will be described in further detail herein.

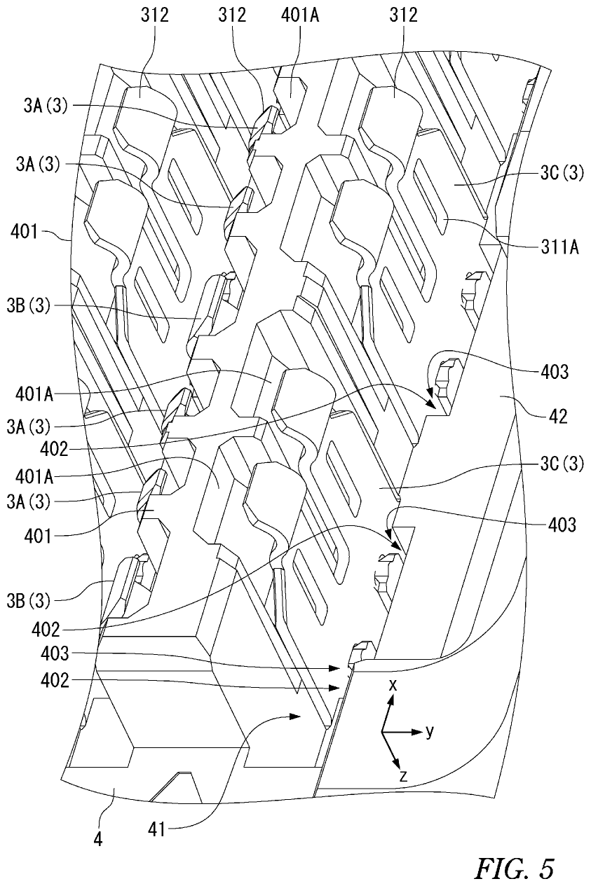

With reference to FIG. 3(a), FIG. 5, and FIGS. 6(a) and 6(b), a specific configuration of the first connector 1 will be described. The second connector 2 is configured in a similar manner to the first connector 1, and as such a detailed description of the same will be omitted. The main housing 4 of the first contact 1 includes an array region 41 which is rectangular as viewed from above and in which the contacts 3 are arranged, and a peripheral region 42 which is a region around the array region and which is required for assembling the main housing with the sub-housing 5. The main housing 4 and the sub-housing 5 are both formed by injection molding from an electrically insulating resin material. The resin material used has a heat resistance required for solder joining.

A ridge 401 protruding toward a mating connector and extending in a predetermined direction (x-direction), and a retaining portion 403 for retaining the contact 3 inserted into a cavity 402 are formed in the array region 41. A plurality of the ridges 401 are arranged at predetermined intervals in a direction (y-direction) orthogonal to their extending direction. Along one y-directional side face of the ridge 401, the signal contacts 3A and the ground contacts 3B are arranged with a predetermined pitch and in a predetermined order in the x-direction. In addition, along the other side face of the ridge 401, the ground shields 3C are arranged with a predetermined pitch.

The contact 3 is inserted into the cavity 402 formed through the main housing 4 in the z-direction from a side opposite to the ridge 401. The contact 3 is inserted into the cavity 402 from its leading end portion 312 side of the contact main body 31. Each contact 3 is retained in the main housing 4 by press-fitting the press-fit protrusions 313 onto an inner wall of the cavity 402 as the retaining portion 403. A press-fitting direction Dp is shown by an arrow in FIG. 6(a). The contact 3 is press-fit to a position in which the stopper protrusion 314 having a wider width than the press-fit protrusion 313 prevents further insertion.

When the ridge 401 formed in the main housing 4 of the second connector 2 is inserted into a space S between the ridges adjacent to each other in the y-direction, the contacts 3 of the same kind are pressed against each other in the y-direction to contact each other in an elastically deformed state. A depression 401A (FIG. 5) for allowing the elastic deformation of the leading end portion 312 is formed in the ridge 401.

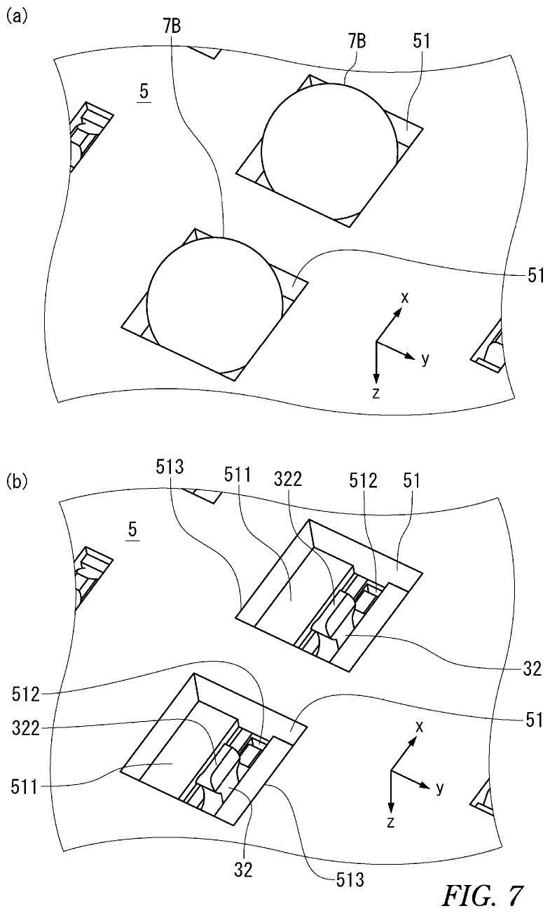

The sub-housing 5 is assembled to the main housing 4 from the joint portion 32 side of the contact 3. The sub-housing 5, as shown in FIG. 1(a) and FIG. 6(b), is formed in a plate-like shape, and is arranged on a face opposite to the array region 41 of the main housing 4. The sub-housing 5 is fastened to the main housing 4 with a plurality of pins 52 or the like arranged in the peripheral region 42. Recesses 51 corresponding to the respective contacts 3 are formed in the sub-housing 5 and in number equal to the total number of contacts. The solder balls 7B (FIG. 7(a)) are arranged in respective ones of the recesses 51. The distal end 322 of the joint portion 32 protrudes into the recess 51 through a rectangular opening 512, as shown in FIG. 7(b). The opening 512 is formed at a y-directional center of a bottom 511. Since the distal end 322 is formed more thinly than the proximal end 321 side, the distal end 322 is easily inserted into the opening 512. In one embodiment, the center line L of the joint portion 32 after insertion and an x-directional center of the bottom 511 coincide with each other.

The solder ball 7B arranged in each recess 51 is formed over the joint portion 32, as shown in FIG. 8(a), by melting the solder ball in the recess by heating, and solidifying it by heat dissipation. The first connector 1 provided with the solder ball 7B is arranged on the first circuit board 11 with a solder paste, not shown, applied to the pad P. The first connector 1 is subjected to a reflow process to cause each contact 3 of the first connector to be joined to the pad of the first circuit board via the solder 7, as shown in FIG. 8(b). It is preferred that the solder 7 solidified after melting wrap the whole joint portion 32, excluding the proximal end 321, without any gap, with the center line L of the joint portion and a center line of the solder coinciding with each other.

In order to keep the contact 3 attached to the solder 7 against an external force, as shown in FIG. 4(c), a part of a contour 30 of the joint portion 32 of each contact as viewed from above is given an anchor shape 301. The joint portion 32 of the present embodiment is enlarged in the widthwise direction x, at the distal end 322 side relative to the proximal end 321, more than a dimension in the widthwise direction x of the proximal end 321, thereby forming the anchor shape 301. The anchor shape 301 of the present embodiment is symmetrical about the center line L of the joint portion 32. The width of the distal end 322 has an upper limit within which the distal end 322 can be inserted into the opening 512 of the sub-housing 5. It should be noted that the shape of the distal end 322 of the joint portion 32 of the present embodiment is formed asymmetrically about the center line L in order to form the shape with a small number of stamping steps and at low cost. The joint portion 32, including the shape of the distal end 322, is not limited to the present embodiment, but may be symmetrical about the center line L.

In FIG. 4(c), the contour 30 of the joint portion 32 is shown in a thick line over a range where the anchor shape 301 is given. The “contour” is equivalent to a line of an external shape of an object. The “external shape” refers to the object's shape as viewed from outside. The anchor shape 301 refers to the shape of the contour 30 that enables a normal vector N1 including a vector component v1 in a direction D2 opposite to a protruding direction D1 of the joint portion 32 to be drawn outward from the contour 30. The phrase “outward from the contour” is equivalent in meaning to starting from the contour toward a space around the contour. In this way, a portion of the distal end 322, and specifically the contour 30 at least partially opposes the solder 7 in the direction of an external force F1 (see FIG. 8(b)). A normal vector N3 is shown in FIG. 4(c) as an example of a normal vector not drawn outward from the contour 30 of the joint portion 32. This normal vector N3 is drawn from the contour 30 toward the joint portion 32 itself, that is, inward from the contour 30.

The normal vector N1 includes the vector component v1 in the opposite direction D2, and a vector component v2 orthogonal to the vector component v1. A normal vector N2 which can be drawn outward from the contour 30 in a range where the anchor shape 301 is not given is different from the normal vector N1 in that the normal vector N2 includes a vector component v3 in the protruding direction D1 and a vector component v4 orthogonal to the vector component v3, and does not include the vector component v1 in the opposite direction D2.

The joint portion 32 is restrained by the solder 7 from the proximal end 321 side over the range where the anchor shape 301 is provided. Therefore, for example, when the first connector 1 is unplugged from the second connector 2, even if the external force F1 in a direction perpendicular to the circuit boards 11,12 acts on the contact 3, or an external force F2 in a direction of rotation on a point, not shown, acts on the contact, as shown in FIG. 8(b), the contact can be kept attached to the solder 7 against such forces FLF2. It should be noted that the external force F2 is not limited to a counterclockwise direction shown in FIG. 8(b), and even if the external force F2 is in a clockwise direction, the contact 3 can be similarly kept attached to the solder 7 based on the anchor shape 301.

A joining strength commensurate with the areas of contact of a front face 32A, a rear face 32B, and a side face 32C of the joint portion 32 with the solder 7 is obtained between the contact 3 and the solder 7. In addition, the anchor shape 301 creates a region of the solder 7 for restraining the joint portion 32 against the external forces F1,F2 (a region 7R encircled by a dashed line in FIG. 8(b)) to resist an unplugging force. This results in an increase in retaining force to retain the contact 3 to the circuit board 11 (or 12) via the solder 7. Since the anchor shape 301 is formed symmetrically about the center line L, an equal retaining force can be secured against both the clockwise external force and the counterclockwise external force F2. In order to form the region 7R of the solder 7 thickly to increase the resistance against unplugging, it is preferred that the anchor shape 301 be formed in a position away to some extent from the proximal end 321 toward the distal end 322 side.

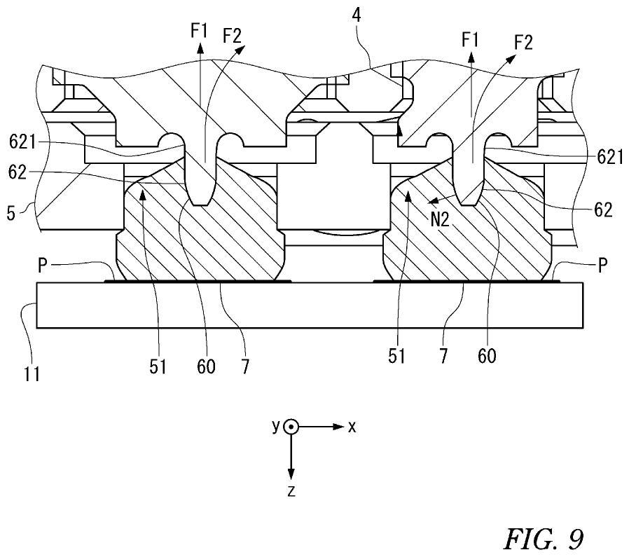

For a contour 60 of a typical joint portion 62 shown as a comparative example in FIG. 9, the normal vector N2 can be drawn outward from the contour 60, but the normal vector N1 including the vector component in the direction D2 opposite to the protruding direction D1 cannot be drawn. That is, the joint portion 62 does not include the anchor shape 301. In that case, even if the respective z-directional lengths and sheet thicknesses of the joint portion 62 of the comparative example and the joint portion 32 of the present embodiment are equal to each other, the area of contact of the joint portion of the comparative example with a solder 7 is smaller than that of the joint portion of the present embodiment with the solder. Therefore, depending on the magnitudes of the external forces F1,F2 acting on the joint portion 62 of the comparative example, the joint portion 62 can be pulled out of the solder 7.

The contact 3 of the present embodiment having the joint portion 32 given the anchor shape 301 has an increased area of contact, thereby increasing the joining strength, as compared with the comparative example (FIG. 9). Therefore, even against a larger pull-out load, or even if the area of contact with the solder 7 is reduced according to miniaturization of the connectors 1,2, a required retaining force can be guaranteed.

An example of a procedure for assembling a circuit structure 100 comprising of the first connector 1, the second connector 2, the first circuit board 11, and the second circuit board 12 will now be described.

For each of the first connector 1 and the second connector 2, the contacts 3 are press-fitted into each of the main housings 4. Thereafter, the sub-housing 5 is assembled to the main housing 4. Next, the solder balls 7B shaped spherically are arranged in the respective recesses 51 of the sub-housing 5, and the assembly of the main housing 4 and the sub-housing is heated. The solder ball 7B is melted by heating using an oven, a heater, or the like, and is solidified by heat dissipation, thereby being joined to the joint portion 32 of the contact 3, as shown in FIG. 8(a). In the process of being softened by heating and sinking into the bottom 511 while wrapping the joint portion 32, the solder ball 7B is guided to the center of the bottom by a square outer peripheral edge 513 of the recess 51. By performing the above procedure for both the first connector 1 and the second connector 2, the first connector 1 and the second connector 2 both including an array of the solder balls 7B (BGA) are realized.

A solder paste is applied (e.g., printed) to the pad P of the first circuit board 11, for example using a metal mask and a squeegee. The solder paste (or solder cream) is composed of a mixture of a finely powdered solder and a flux. The first connector 1 is placed on the first circuit board 11 with the solder ball 7B positioned on the pad P, and the first connector and the first circuit board are heated in a reflow oven to a predetermined temperature, which causes the solder ball 7B and the solder in the solder paste to melt. Thereafter, the solder 7 solidified by heat dissipation joins each contact 3 to the pad P, as shown in FIG. 8(b), and thus a first assembly Al (FIG. 2(b)) composed of the first connector 1 and the first circuit board 11 is realized. Regarding the second circuit board 12 and the second connector 2, similarly, by performing printing of the solder paste and heating in the reflow oven, each contact 3 of the second connector 2 is joined to the pad P of the second circuit board 12, and thus a second assembly A2 (FIG. 2(a)) composed of the second connector 2 and the second circuit board 12 is produced.

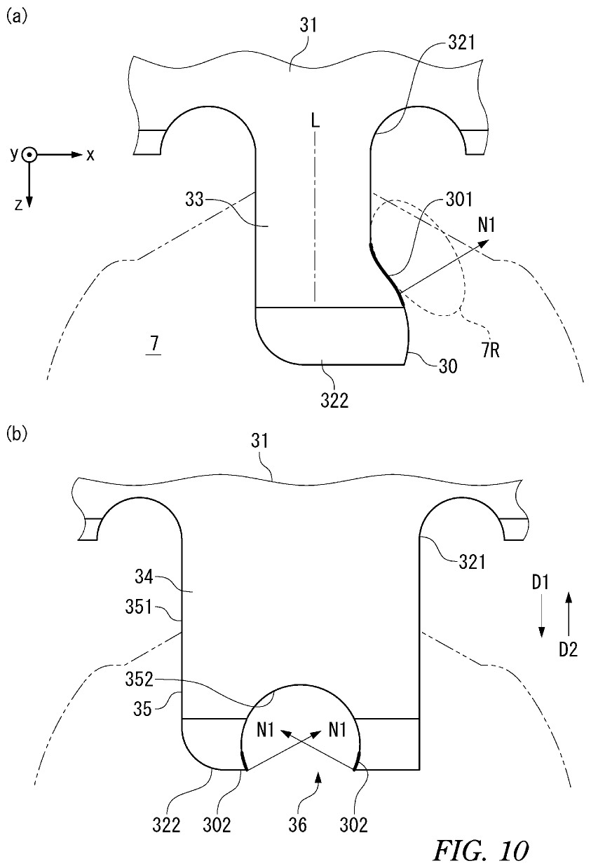

Referring to a joint portion 33 of a contact shown in FIG. 10(a), the anchor shape 301 (i.e., an expanded width of the distal end 322) may be given to only one side in the widthwise direction x. In this embodiment, based on the anchor shape 301, the joining strength between the solder 7 and the joint portion 33 increases, as does the breaking strength of the region 7R of the solder 7 for restraining the joint portion 33 from the proximal end 321 side against an external force. The area of the joint portion 33 is smaller than that of the joint portion 32 of the above embodiment. As a result, the retaining force can be improved at least as compared with the comparative example, while saving material used for the contact, such as a copper alloy.

The joint portions of each of the contacts 3 included in the first connector 1 and/or the second connector 2 may not necessarily have the same shape. For example, the contact including the joint portion 32 (FIGS. 8(a) and 8(b)) of the above embodiment and the contact including the joint portion 33 of the first modification may coexist in the same connector. In this case, based on an analysis or the like of a retaining force when the connectors are divided into a plurality of regions, for example, the contact 3 including the joint portion 32 of the above embodiment can be arranged in a region where the retaining force required for the solder and the contact is relatively large, whereas the contact including the joint portion 33 of the first modification can be arranged in a region where the retaining force required is relatively small. Based on the analysis or the like, the contact including the joint portion 62 of the comparative example which is not given the anchor shape can also be arranged in some regions of the connector. Two or more kinds of joint portions, including contacts including joint portions of the following modifications, are may coexist in the same connector. The joint portion of the signal contact 3A, the joint portion of the ground contact 3B, and the joint portion of the ground shield 3C may be given their own respective shapes.

Second to fifth modifications, which will be described below, all increase the joining strength based on their own respective anchor shapes, and can simultaneously obtain the breaking strength of the region 7R of the solder 7 for restraining the joint portion against an external force, and therefore the retaining force to keep the contacts attached to the circuit boards 11,12 via the solder is improved.

Referring to a joint portion 34 of a contact shown in FIG. 10(b), a notch 36 including an anchor shape 302 may be formed in a part of a contour 35. The joint portion 34 is formed in a substantially rectangular shape, and has the circular arc-like notch 36 formed from the position of the distal end 322 toward the proximal end 321. The contour 35 includes an outer peripheral contour 351 of the joint portion 34 and an inner peripheral contour 352 of the notch 36. The anchor shape 302 is provided in the vicinity of opposite ends of the inner peripheral contour 352. Such an anchor shape 302, like the anchor shape 301 described above, is also equivalent to the shape that enables the normal vector N1 including the vector component in the direction D2 opposite to the protruding direction D1 to be drawn outwardly from the contour 352. In this way, the contour 35 at least partially opposes solder 7 fixed thereto in the direction D2 opposite to the protruding direction D1.

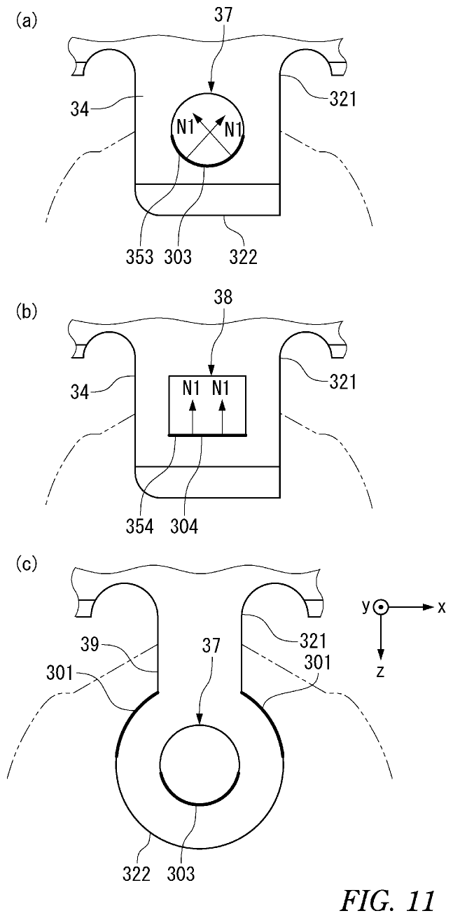

As shown in FIG. 11(a), instead of the notch 36, a circular opening 37 may be formed in the joint portion 34. An anchor shape 303 that enables the normal vector Ni to be drawn is given to the distal end 322 side of an inner peripheral contour 353 of the opening 37. As shown in FIG. 11(b), an opening 38 closed about its perimeter is formed in the joint portion 34, for example in a rectangular shape. An anchor shape 304 that enables the normal vector Ni to be drawn is given to a contour 354 of the opening 38. It should be understood other suitable shapes may be given to the opening 38 without departing from the scope of the present disclosure.

A joint portion 39 of a contact shown in FIG. 11(c) includes two types of anchor shapes 301,303 defined in a ring-shaped end of the joint portion 39. Specifically, the outer shape of the joint portion 39 is formed in a substantially circular shape. Therefore, the joint portion 39 is enlarged in the widthwise direction x, at the distal end 322 side relative to the proximal end 321, more than the dimension in the widthwise direction x of the proximal end, thereby forming the anchor shape 301. In addition, the circular opening 37, for example, is formed in the center of the outer shape of the joint portion 39, and therefore the anchor shape 303 is given to the inner peripheral contour 353 of the opening.

In addition, any suitable one or more anchor shapes that enable the normal vector Ni to be drawn may be given to the joint portion of the contact. For example, by forming the notch 36 (FIG. 10(b)) in the distal end 322 of the joint portion 32 (FIGS. 8(a) and 8(b)) of the above embodiment, the anchor shapes 301,302 are formed in the contour 30 of the joint portion. In the above second to fifth modifications, the anchor shapes 301 to 304 are all formed symmetrically about the center line L of the joint portion, but the anchor shapes 301 to 304 may be asymmetrical about the center line L.

In addition to the above, the configurations mentioned in the above embodiment may be selectively adopted or removed, or may be appropriately changed into any other configuration, unless such selective adoption/removal or change departs from the spirit of the present invention. For example, if the contact 3 is press-fitted into the housing from a direction opposite to the press-fitting direction Dp shown in FIG. 6(a), the recess 51 in which the joint portion 32 and the solder ball 7B are located may be formed in the main housing 4. In this case, the sub-housing 5 is not required.

An application example of the connector of the present invention is not limited to the circuit structure 100 including the two circuit boards 11,12 as in the above embodiment. For example, the connector of the present invention may be to connect an IC package and a circuit board. In this case, a first object to be connected of the contact is equivalent to a pin of the IC package.

In addition, those areas in which it is believed that those of ordinary skill in the art are familiar, have not been described herein in order not to unnecessarily obscure the invention described. Accordingly, it has to be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A contact for electrically connecting a first object to a second object, comprising:
a main body adapted to be connected to the first object; and
a joint portion protruding from the main body and adapted to be joined to the second object via solder, a first portion of a contour of the joint portion at least partially facing in a first direction opposite a protruding direction of the joint portion.

2. The contact according to claim 1, wherein the first portion of the contour is formed in an anchor shape and defines a normal vector extending outwardly from the contour and including a vector component extending in the first direction.

3. The contact according to claim 2, wherein the anchor shape is symmetric about a center line of the joint portion set parallel with a plugging direction of the contact.

4. The contact according to claim 2, wherein the anchor shape is asymmetric about a center line of the joint portion set parallel with a plugging direction of the contact.

5. The contact according to claim 1, further comprising a solder ball arranged at the joint portion.

6. The contact according to claim 1, wherein the main body is adapted to be connected to the first object in a plugging direction, a distal end of the joint portion opposite the main body having a width in a direction orthogonal to the plugging direction that is greater than a width of a proximal end of the joint portion defined adjacent the main body.

7. The contact according to claim 1, wherein a notch is formed in the joint portion, the first portion of the contour defined by the notch.

8. The contact according to claim 7, wherein the notch is formed into a distal end of the joint portion opposite the main body.

9. The contact according to claim 1, wherein an opening closed about its perimeter is formed through the joint portion, the first portion of the contour defined within the opening.

10. The contact according to claim 1, wherein the contour defined by the joint portion includes a first contour and a second contour, the first contour formed on an outwardly facing surface of the joint portion and the second contour formed on an inwardly facing surface of the joint portion, each of the first and second contours at least partially facing in the first direction.

11. The contact according to claim 10, wherein an end of the joint portion defines a ring having a central opening, the first contour defined on an outwardly facing surface of the ring, and the second contour defined by the central opening.

12. A connector, comprising:
a housing including a plurality of contact openings;
a plurality of contacts arranged within the plurality of contact openings, each contact including:
a main body adapted to be connected to a mating contact; and
a joint portion protruding from the main body and adapted to be joined to a substrate via solder, a first portion of a contour of the joint portion at least partially facing in a first direction opposite a protruding direction of the joint portion.

13. The connector according to claim 12, wherein the first portion of the contour is formed in an anchor shape and defines a normal vector extending outwardly from the contour and including a vector component extending in the first direction.

14. The connector according to claim 12, wherein the main body is adapted to be connected to the mating contact in a plugging direction, a distal end of the joint portion opposite the main body having a width in a direction orthogonal to the plugging direction that is greater than a width of a proximal end of the joint portion defined adjacent the main body.

15. A connector assembly, comprising:
a contact housing;
a substrate including a conductive solder pad; and
a contact arranged in the contact housing, including:
a main body adapted to be connected to a mating contact on a first end thereof; and
a joint portion protruding from a second end of the main body opposite the first end in a first direction, the joint portion adapted to be joined to the solder pad via solder, a portion of a contour of the joint portion at least partially facing in a second direction opposite the first direction.

16. The connector assembly according to claim 15, wherein the portion of the contour is formed in an anchor shape and defines a normal vector extending outwardly from the contour and including a vector component extending in the second direction.

17. The connector assembly according to claim 15, wherein the substrate is a printed circuit board.

18. The connector assembly according to claim 15, wherein the solder surrounds a distal end of the joint portion opposite the main body.

19. The connector assembly according to claim 15, wherein the solder opposes at least a portion of the joint portion in the second direction.

20. The connector assembly according to claim 15, wherein the portion of the contour is defined by at least one of a notch or an opening formed through the joint portion.
